(19) United States
(12) Patent Application Publication
(10) Pub. No.: US 2015/0035550 A1
(43) Pub. Date: Feb. 5, 2015

(54) HIGH ACCURACY MEASUREMENT OF ON-CHIP COMPONENT PARAMETERS

(71) Applicant: QUALCOMM INCORPORATED, San Diego, CA (US)

(72) Inventors: Rajkumar Chinnakonda Kubendran, Marlborough, MA (US); Xinwei Wang, Dunstable, MA (US); Xiandong Zhang, Westford, MA (US)

(73) Assignee: QUALCOMM INCORPORATED, San Diego, CA (US)

(21) Appl. No.: 13/959,504

(22) Filed: Aug. 5, 2013

(51) Int. Cl. G01R 27/26

(52) U.S. Cl. CPC G01R 27/2605
USPC 324/686

(57) ABSTRACT

Techniques for measuring on-chip component parameters are described herein. In one embodiment, a method for measuring one or more on-chip component parameters comprises measuring a time for an on-chip capacitor to charge to a voltage approximately equal to a reference voltage, and measuring a time for the on-chip capacitor to charge to a voltage approximately equal to a voltage across an on-chip component. The method also comprises determining a parameter of the on-chip component based on the measured time for the on-chip capacitor to charge to the voltage approximately equal to the reference voltage, the measured time for the on-chip capacitor to charge to the voltage approximately equal to the voltage across the on-chip component, and the reference voltage.

### BACKGROUND

1. Field

Aspects of the present disclosure relate generally to integrated circuits, and more particularly, to measurement of on-chip component parameters.

2. Background

Die process-voltage-temperature (PVT) variations of basic circuit components can affect design performance drastically. Therefore, it is important to measure these variations reliably. Many measurement techniques have been developed to measure capacitance, resistance and other on-chip component parameters.

In one technique, the resistance of an on-chip resistor is measured by passing a reference current through the resistor and measuring the voltage drop across the resistor (which is proportional to the resistance) using a high-resolution analog-to-digital converter (ADC). Capacitance of an on-chip capacitor is then measured by coupling the resistor and the capacitor into a ring oscillator and measuring the oscillation time period of the ring oscillator, which is proportional to the resistance and capacitance of the resistor and the capacitor. Since the resistance of the resistor is known from the previous measurement, the capacitance of the capacitor can be determined based on the oscillation time period and the resistance of the resistor.

A drawback of this technique is that it requires a high-resolution ADC (which takes up a large die area) and an external resistor to calibrate resistance and then capacitance. Further, this technique uses two different circuit topologies for measuring resistance and capacitance, adding complexity to the chip.

### SUMMARY

The following presents a simplified summary of one or more embodiments in order to provide a basic understanding of such embodiments. This summary is not an extensive overview of all contemplated embodiments, and is intended to neither identify key or critical elements of all embodiments nor delineate the scope of any or all embodiments. Its sole purpose is to present some concepts of one or more embodiments in a simplified form as a prelude to the more detailed description that is presented later.

According to an aspect, a method for measuring one or more on-chip component parameters is described herein. The method comprises measuring a time for an on-chip capacitor to charge to a voltage approximately equal to a reference voltage, and measuring a time for the on-chip capacitor to charge to a voltage approximately equal to a voltage across an on-chip component. The method also comprises determining a parameter of the on-chip component based on the measured time for the on-chip capacitor to charge to the voltage approximately equal to the reference voltage, the measured time for the on-chip capacitor to charge to the voltage approximately equal to the voltage across the on-chip component, and the reference voltage.

A second aspect relates to an apparatus for measuring one or more on-chip component parameters. The apparatus comprises means for measuring a time for an on-chip capacitor to charge to a voltage approximately equal to a reference voltage, and means for measuring a time for the on-chip capacitor to charge to a voltage approximately equal to a voltage across an on-chip component. The apparatus also comprises means for determining a parameter of the on-chip component based on the measured time for the on-chip capacitor to charge to the voltage approximately equal to the reference voltage, the measured time for the on-chip capacitor to charge to the voltage approximately equal to the voltage across the on-chip component, and the reference voltage.

A third aspect relates to an apparatus for measuring one or more on-chip component parameters. The apparatus comprises a voltage comparator having a first input, a second input, and an output. The apparatus also comprises a first mode switch for selectively connecting a reference voltage to the first input of the voltage comparator, a second mode switch for selectively connecting an on-chip component to the first input of the voltage comparator, an on-chip capacitor coupled to the second input of the comparator, and a counter coupled to the output of the voltage comparator. The apparatus further comprises a controller, wherein, in a first measurement mode, the controller is configured to close the first mode switch, open the second mode switch and trigger the counter to start counting, and, in a second measurement mode, the controller is configured to open the first mode switch, close the second mode switch and trigger the counter to start counting. The counter is configured to stop counting when the output of the voltage comparator toggles from a first output value to a second output value.

A fourth aspect relates to a method for measuring differential capacitance. The method comprises measuring a time for a first on-chip capacitor to charge to a voltage approximately equal to a reference voltage, and determining a capacitance of the first on-chip capacitor based on the measured time for the first on-chip capacitor to charge to the voltage approximately equal to the reference voltage, and the reference voltage. The method also comprises measuring a time for a second on-chip capacitor to charge to a voltage approximately equal to the reference voltage, and determining a capacitance of the second on-chip capacitor based on the measured time for the second on-chip capacitor to charge to the voltage approximately equal to the reference voltage, and the voltage reference. The method further comprises determining a differential capacitance between the first and second on-chip capacitors by taking a difference between the determined capacitance of the first on-chip capacitor and the determined capacitance of the second on-chip capacitor.

To the accomplishment of the foregoing and related ends, the one or more embodiments comprise the features hereinafter fully described and particularly pointed out in the claims. The following description and the annexed drawings set forth in detail certain illustrative aspects of the one or more embodiments. These aspects are indicative, however, of but a few of the various ways in which the principles of various embodiments may be employed and the described embodiments are intended to include all such aspects and their equivalents.

### BRIEF DESCRIPTION OF THE DRAWINGS

FIG. 1 shows a measurement module according to an embodiment of the present disclosure.

FIG. 2 is a timing diagram illustrating measurement of capacitance according to an embodiment of the present disclosure.

FIG. 3 shows a measurement module for measuring differential capacitance according to an embodiment of the present disclosure.

FIG. 4 shows a measurement module for measuring transistor parameters according to an embodiment of the present disclosure.

FIG. 5 shows a current source according to an embodiment of the present disclosure.

FIG. 6 shows a measurement module for calibrating a temperature sensor according to an embodiment of the present disclosure.

FIG. 7 is a flow diagram of a method for measuring one or more on-chip component parameters according to an embodiment of the present disclosure.

FIG. 8 is a flow diagram of a method for measuring a differential capacitance according to an embodiment of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

Embodiments of the present disclosure address the drawbacks of current techniques for measuring on-chip component parameters by providing integrated designs that can measure different on-chip component parameters (e.g., resistance, capacitance, and MOS transistor parameters) using a single circuit topology.

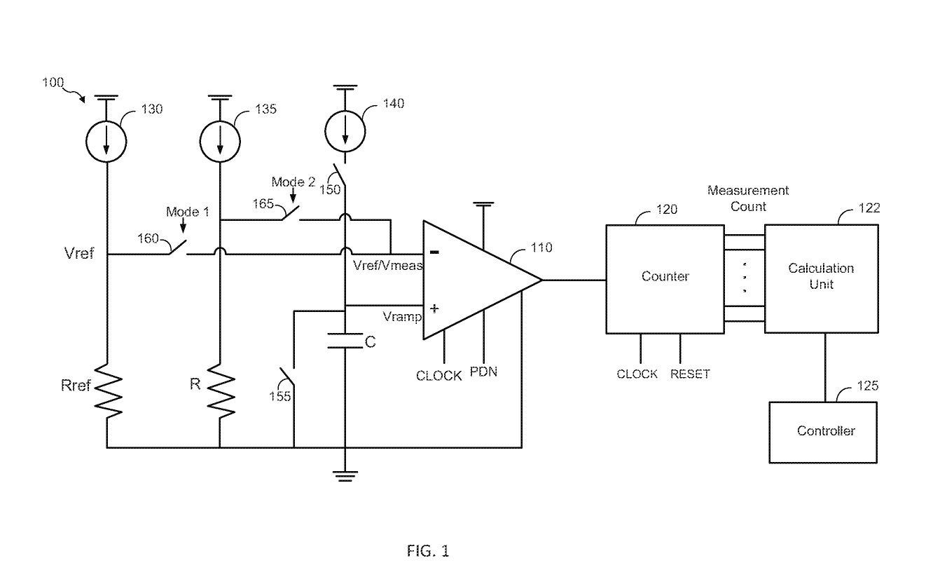

FIG. 1 shows a measurement module 100 for measuring on-chip component parameters according to an embodiment of the present disclosure. The module 100 comprises a voltage comparator 110, a counter 120, a first reset switch 150, a second reset switch 155, a first mode switch 160, a second mode switch 165, a first current source 130, a second current source 135, a third current source 140, a reference resistor Rref, a calculation unit 122, and a controller 125. In the example in FIG. 1, the module 100 is configured to measure the capacitance of on-chip capacitor C and the resistance of on-chip resistor R. The on-chip resistor R may comprise polysilicon, metal and/or other material.

The first reset switch 150 selectively connects the top terminal of the on-chip capacitor C to the third current source 140, and the second reset switch 155 selectively connects the top terminal of the on-chip capacitor C to ground. The first and second reset switches 150 and 155 are controlled by the controller 125, as discussed further below. For ease of illustration, the connections between the controller 125 and the first and second reset switches 150 and 155 are not shown in FIG. 1. The top terminal of the on-chip capacitor C is connected to the positive input of the voltage comparator 110.

The first mode switch 160 selectively connects the reference resistor Rref to the negative input of the voltage comparator 110, and the second mode switch 165 selectively connects the on-chip resistor R to the negative input of the voltage comparator 110. The first and second mode switches 160 and 165 are controlled by the controller 125. For ease of illustration, the connections between the controller 125 and the first and second mode switches 160 and 165 are not shown in FIG. 1. The reference resistor Rref is connected to the first current source 130, and the on-chip resistor R is connected to the second current source 135.

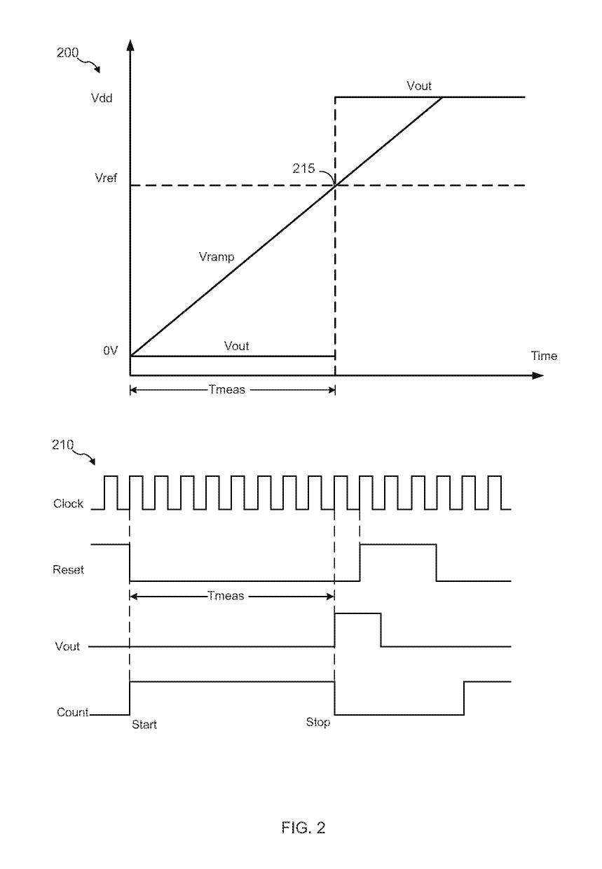

Operations for measuring the capacitance of the on-chip capacitor C will now be described with reference to FIGS. 1 and 2.

Initially, the controller 125 opens the first reset switch 150 and closes the second reset switch 155. This causes any charge on the capacitor C to discharge to ground, thereby setting the voltage across the capacitor C to approximately zero volts. Thus, the controller 125 sets the voltage across the capacitor C to zero volts as an initial condition for the capacitance measurement.

The current from the first current source 130 passes through the reference resistor Rref. The resulting voltage drop across the reference resistor Rref provides a reference voltage Vref. The controller 125 opens the second mode switch 165 and closes the first mode switch 160, which connects the reference voltage Vref to the negative input of the voltage comparator 110 through the first mode switch 160. Thus, the reference voltage Vref is input to the negative input of the voltage comparator 110 and the voltage across the on-chip capacitor C (which is initially set to zero volts) is input to the positive input of the voltage comparator 110.

The controller 125 then closes the first reset switch 150 and opens the second reset switch 155. As a result, current from the third current source 140 starts charging the on-chip capacitor C, causing the voltage across the on-chip capacitor C (denoted Vramp in FIGS. 1 and 2) to rise at a rate that is inversely proportional to the capacitance of the on-chip capacitor C. At approximately the same time, the controller 125 triggers the counter 120 to start counting at a rate set by a clock signal. Thus, the count value of the counter 140 provides a measure of time from the time that the on-chip capacitor C starts charging.

Initially, the reference voltage Vref is greater than the voltage across the on-chip capacitor C. As a result, the output voltage of the comparator 110 is initially logic zero. The voltage across the on-chip capacitor C rises as the on-chip capacitor C is charged by the third current source 140. Eventually, the voltage across the on-chip capacitor C crosses the reference voltage Vref. At this point, the output voltage of the comparator 110 toggles from logic zero to logic one. This causes the counter 120 to stop counting. As a result, the count value at which the counter 120 stops counting provides a measure of the time it takes for the on-chip capacitor C to charge to a voltage equal to the reference voltage Vref. The calculation unit 122 may then determine the capacitance of the on-chip capacitor C based on the following equation:

$$Cmeas = \frac{Iref \cdot Tmeas}{Vref} \qquad ( 1 )$$

where Iref is the current of the third current source 140, Tmeas is the time it takes for the on-chip capacitor C to charge to a voltage equal to the Vref as indicated by the count value, and Cmeas is the determined capacitance. Assuming that Iref and Vref are known with high accuracy, the module 100 can be used to determine the capacitance of the on-chip capacitor C with high accuracy.

FIG. 2 shows a timing diagram 200 of the voltage across the capacitor C (denoted Vramp) and the output voltage of the comparator 110 (denoted Vout) during charging of the capacitor C. At the start of charging, the voltage across the capacitor C is approximately zero volts, and the output voltage of the comparator 110 is approximately zero volts (logic zero). As the capacitor C is charged by the third current source 140, the voltage across the capacitor C rises at a rate that is inversely proportional to the capacitance of the capacitor C. Eventually, the voltage across the capacitor C crosses the reference voltage Vref (point 215 in FIG. 2), at which time the output voltage of the comparator 110 toggles from approximately zero volts to approximately the power-supply voltage Vdd (logic one) of the comparator 110.

FIG. 2 also shows a timing diagram 210 of the clock signal, a reset signal, the output voltage of the comparator 110, and a count signal. The reset signal may be output by the controller 125 to control the first and second reset switches 150 and 155 and to trigger the counter 120, as discussed below.

When the reset signal is logic one, the first reset switch 150 is opened and the second reset switch 155 is closed, thereby discharging the capacitor C to zero volts. When the reset signal switches from logic one to logic zero, the first reset switch 150 is closed and the second reset switch 155 is opened, thereby connecting the capacitor C to the third current source 140. At this time, the current from the third current source 140 starts charging the capacitor C, and the voltage across the capacitor C starts rising from zero volts (shown in timing diagram 200). In this example, the first reset switch 150 may be implemented using a P-type metal-oxide-semiconductor (PMOS) transistor and the second reset switch 155 may be implemented using an N-type metal-oxide-semiconductor (NMOS) transistor with the gates of the PMOS and NMOS transistors driven by the reset signal.

When the reset signal is logic one, the counter 120 is reset. When the reset signal switches from logic one to logic zero, the counter 120 starts counting. Thus, the counter 120 is triggered when the reset signal switches from logic one to logic zero. This is represented by the count signal in the timing diagram 210. As a result, the count value of the counter 120 provides a measure of time from the time that the capacitor C starts charging. The counter 120 may increment the count value for each cycle (period) of the clock signal. The higher the clock frequency, the higher the resolution of the time measurement provided by the count value.

When the voltage across the capacitor C crosses the reference voltage Vref, the output voltage of the comparator 110 toggles from logic zero to logic one, at which time the counter 120 stops counting. The count value when the counting stops provides a measure of the time it takes for the capacitor C to charge up to the reference voltage Vref. This allows the calculation unit 125 to determine the capacitance of the capacitor C using the count value and equation (1) above.

Returning to FIG. 1, operations for measuring the on-chip resistor R will now be described with reference to FIG. 1.

Initially, the controller 125 opens the first reset switch 150 and closes the second reset switch 155. This causes the capacitor C to discharge to ground, thereby resetting the voltage across the capacitor C to approximately zero volts.

The current from the second current source 135 passes through the on-chip resistor R, resulting in a voltage drop across the resistor R that is proportional to the resistance of the resistor R. The controller 125 opens the first mode switch 160 and closes the second mode switch 165, thereby connecting the voltage across the resistor R to the negative input of the voltage comparator 110 through the second mode switch 165. Thus, the voltage drop across the resistor R is input to the negative input of the voltage comparator 110 and the voltage across the on-chip capacitor C (which is initially set to zero volts) is input to the positive input of the voltage capacitor 110.

The controller 125 then closes the first reset switch 150 and opens the second reset switch 155. As a result, current from the third current source 140 starts charging the capacitor C, causing the voltage across the capacitor C to rise. At approximately the same time, the controller 125 triggers the counter 120 to start counting. Thus, the count value of the counter 120 provides a measure of time from the time that the capacitor C starts charging.

Initially, the voltage drop across the resistor R is greater than the voltage across the capacitor C. As a result, the output voltage of the comparator 110 is initially logic zero. The voltage across the capacitor C rises as the capacitor C is charged by the third current source 140. Eventually, the voltage across the capacitor C crosses the voltage drop across the resistor R, at which time, the output voltage of the comparator 110 toggles from logic zero to logic one. This causes the counter 120 to stop counting. As a result, the count value when the counter 120 stops counting provides a measure of the time it takes for the on-chip capacitor C to charge to a voltage equal to the voltage drop across the resistor R. The calculation unit 122 may then determine the voltage drop across the resistor R based on the following equation:

$$Vmeas = \frac{{T}_{2}}{{T}_{1}} \cdot Vref \qquad ( 2 )$$

where T₂ is the time it takes for the capacitor C to charge to a voltage equal to the voltage across the resistor R as indicated by the count value, T₁ is the time it takes the capacitor C to charge to a voltage equal to the reference voltage Vref as indicated by the previous count value, and Vmeas is the determined voltage across the resistor R. Thus, the voltage across the resistor R is given by the reference voltage Vref times a ratio of the time it takes the capacitor C to charge up to the voltage across the resistor R and the time it takes the capacitor C to charge up to the reference voltage Vref. Once the voltage across the resistor R is determined, the calculation unit 122 may determine the resistance of the resistor R by dividing the voltage across the resistor R by the current of the second current source 135.

Thus, the measurement module 100 provides a single circuit topology capable of measuring both on-chip capacitance and on-chip resistance. This reduces complexity and die area taken up by the measurement module compared with current measurement techniques that use two different circuit topologies (i.e., a high-resolution ADC and an oscillator) to measure on-chip resistance and on-chip capacitance.

The voltage comparator 110 may be implemented using a latched voltage comparator driven by a clock signal. During each clock cycle (period), the latched comparator may be reset and, after being reset, use positive feedback (e.g., from cross-coupled inverters) to quickly convert the sign of the voltage difference between the inputs of the comparator into a full-swing voltage at the output of the comparator. For example, the comparator may output a voltage equal to the power-supply voltage Vdd (logic one) when the voltage difference is positive (the voltage at the positive input is greater than the voltage at the negative input), and output zero volts (logic zero) when the voltage difference is negative (the voltage at the negative input is greater than the voltage at the positive input). Thus, the latched comparator outputs a logic value indicating the sign of the voltage difference between the inputs of the comparator during each clock cycle.

The latched comparator and the counter 120 may be driven by the same clock signal. In this embodiment, the counter 120 may detect the output logic value of the comparator during each clock cycle, and determine whether to stop counting based on the logic value. For example, the counter 120 may stop counting when the output logic value changes from logic zero in one clock cycle to logic one in the next clock cycle. It is to be appreciated that the voltage comparator 110 may also be implemented using a continuous-time voltage comparator instead of a latched voltage comparator.

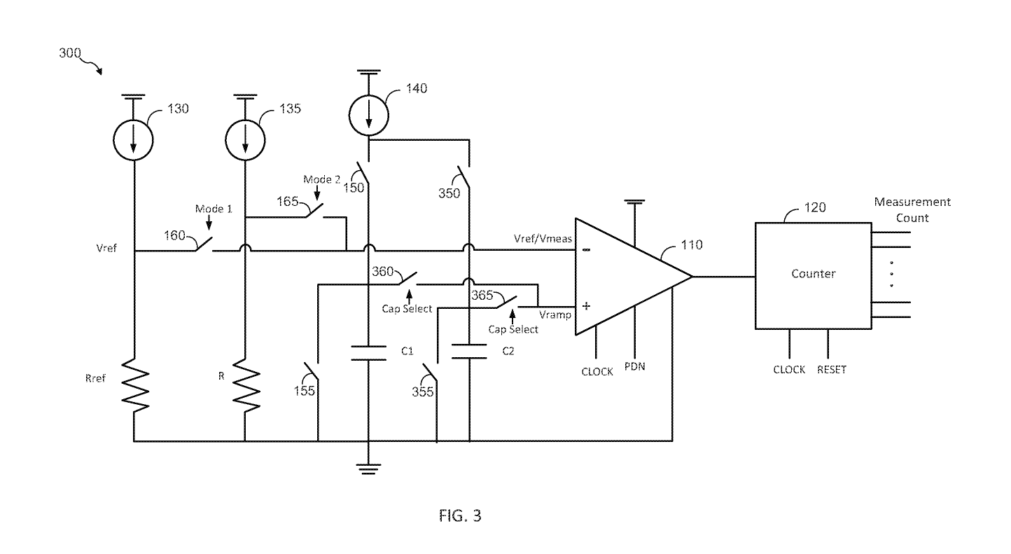

FIG. 3 shows a measurement module 300 according to another embodiment of the present disclosure. The module 300 is similar to the module 100 in FIG. 1 and further comprises a first on-chip capacitor C1, a second on-chip capacitor C2, a third reset switch 350, a fourth reset switch 355, a first capacitor-select switch 360 and a second capacitor-select switch 365. The measurement module 300 may also include the calculation unit 122 and the controller 125, both of which are not shown in FIG. 3 for ease of illustration.

The measurement module 300 is configured to measure the differential capacitance between the first and second capacitors C1 and C2, as discussed further below. The differential capacitance removes sources of measurement error that are common to both capacitors, thereby providing higher accuracy. The common sources of error may include input capacitance of the comparator 110, parasitic capacitance from metal wire routing and/or input offset of the comparator 110.

The first reset switch 150 selectively connects the top terminal of the first capacitor C1 to the third current source 140, and the second reset switch 155 selectively connects the top terminal of the first capacitor C1 to ground. The third reset switch 350 selectively connects the top terminal of the second capacitor C2 to the third current source 140, and the fourth reset switch 355 selectively connects the top terminal of the second capacitor C2 to ground. The first capacitor-select switch 360 selectively connects the top terminal of the first capacitor C1 to the positive input of the comparator 110, and the second capacitor-select switch 365 selectively connects the top terminal of the second capacitor C2 to the positive input of the comparator 110. The switches 150, 155, 350, 355, 360 and 365 may be controlled by the controller 125 (not shown in FIG. 3).

Operations for measuring the differential capacitance between the first and second capacitors C1 and C2 will now be described.

The measurement module 300 measures the capacitance of the first capacitor C1 and the capacitance of the second capacitor C2 separately. The calculation unit 122 then takes the difference between the measured capacitances to determine the differential capacitance between the first and second capacitors C1 and C2. To measure the capacitance of the first capacitor C1, the controller 125 closes the first capacitor-select switch 360 and opens the second capacitor-select switch 365. As a result, the top terminal of the first capacitor C1 is connected to the positive input of the comparator 110 through the first capacitor-select switch 360. The controller 125 also closes the first mode switch 160 to connect the reference voltage Vref to the negative input of the comparator 110.

Initially, the controller 125 opens the first reset switch 150 and closes the second reset switch 155 to discharge the first capacitor C1 to ground, thereby setting the voltage across the first capacitor C1 to zero volts. The controller 125 then closes the first reset switch 150 and opens the second reset switch 155, allowing the third current source 140 to charge the first capacitor C1. At about this time, the controller 125 triggers the counter 120 to begin counting. The counter 120 stops counting when the voltage across the first capacitor C1 crosses the reference voltage Vref. Thus, the count value when the counter 120 stops counting provides a measurement of the time it takes for the first capacitor C1 to charge to a voltage equal to the reference voltage Vref. The calculation unit 122 may then determine the capacitance of the first capacitor C1 using equation (1) and the time for the first capacitor C1 to charge up the reference voltage Vref as indicated by the count value. During the time that the first capacitor C1 is charging, the third reset switch 350 is open to prevent the second capacitor C2 from charging.

To measure the capacitance of the second capacitor C2, the controller 125 closes the second capacitor-select switch 365 and opens the first capacitor-select switch 360. As a result, the top terminal of the second capacitor C2 is connected to the positive input of the comparator 110 through the second capacitor-select switch 365. The controller 125 also closes the first mode switch 160 to connect the reference voltage Vref to the negative input of the comparator 110.

Initially, the controller 125 opens the third reset switch 350 and closes the fourth reset switch 355 to discharge the second capacitor C1 to ground, thereby setting the voltage across the second capacitor C2 to zero volts. The controller 125 then closes the third reset switch 350 and opens the fourth reset switch 355, allowing the third current source 140 to charge the second capacitor C2. At about this time, the controller 125 triggers the counter 120 to begin counting. The counter 120 stops counting when the voltage across the second capacitor C2 crosses the reference voltage Vref. Thus, the count value when the counter 120 stops counting provides a measurement of the time it takes for the second capacitor C2 to charge to a voltage equal to the reference voltage Vref. The calculation unit 122 may then determine the capacitance of the second capacitor C2 using equation (1) and the time for the second capacitor C2 to charge up the reference voltage Vref as indicated by the count value. During the time that the second capacitor C2 is charging, the first reset switch 150 is open to prevent the first capacitor C1 from charging.

After the capacitance of the first capacitor C1 and the capacitance of the second capacitor C2 are determined, the calculation unit 122 determines the differential capacitance by taking the difference between the capacitance of the first capacitor C1 and the capacitance of the second capacitor C2.

Since the first capacitor C1 and the second capacitor C2 are fabricated on the same chip, and therefore subject to approximately the same process conditions, the capacitance of the first capacitor C1 relative to the capacitance of second capacitor C2 may be known with high accuracy. This allows the capacitance of the first capacitor C1 and the capacitance of the second capacitor C2 to be re-determined from the differential capacitance with high accuracy. For example, if the first capacitor C1 is fabricated to have twice the chip area of the second capacitor C2, then it may be assumed that the capacitance of the first capacitor C1 is twice the capacitance of the second capacitor C2. In this example, the calculation unit 122 may determine the capacitance of the first capacitor C1 to be equal to twice the differential capacitance, and the capacitance of the second capacitor C2 to be equal to the differential capacitance. Using the differential capacitance to determine the capacitances of the first and second capacitors C1 and C2 increases accuracy because the differential capacitance removes sources of measurement errors that are common to both capacitors, as discussed above.

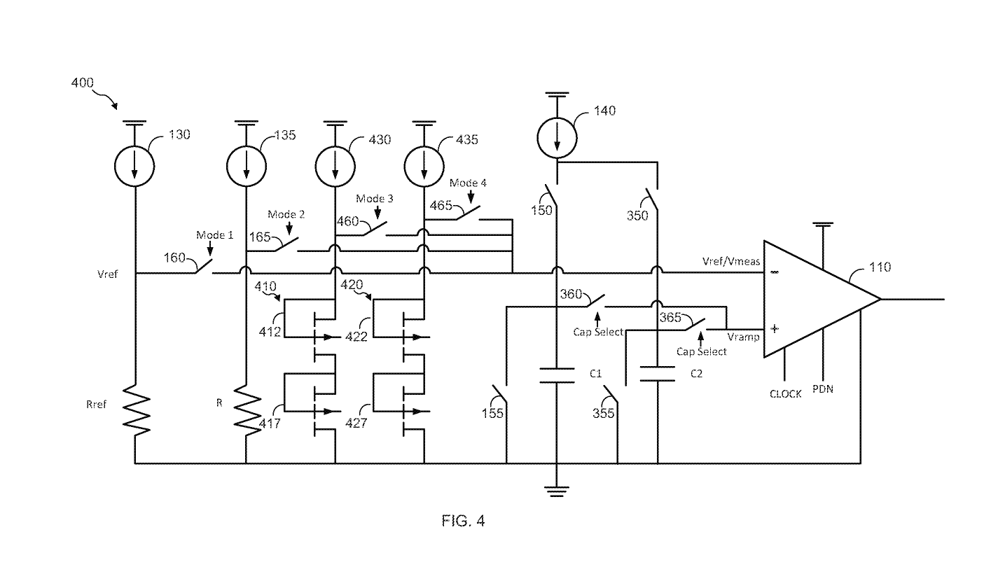

FIG. 4 shows a measurement module 400 according to another embodiment of the present disclosure. The module 400 is similar to the module 300 in FIG. 3 and further comprises a first stack of diode-connected transistors 410, a second stack of diode-connected transistors 420, a third mode switch 460, a fourth mode switch 465, a fourth current source 430, and a fifth current source 435. Each of the transistors may comprise an NMOS transistor or another type of transistor. The module 400 is configured to measure the K values and/or threshold voltages of the transistors, as discussed further below. The K value for each transistor may be given by:

$$K = \frac{{μ}_{n} {C}_{ox}}{4} \frac{W}{L} \qquad ( 3 )$$

where μₙ is electron mobility in the inversion layer, Cₒₓ is the oxide capacitance per unit area, W is the gate width, and L is the gate length.

The third mode switch 460 selectively connects the first stack of diode-connected transistors 410 to the negative input of the comparator 110, and the fourth mode switch 465 selectively connects the second stack of diode-connected transistors 420 to the negative input of the comparator 110. The first and second mode switches 460 and 465 may be controlled by the controller 125 (not shown in FIG. 3).

The first stack of diode-connected transistors 410 comprises two diode-connected transistors 412 and 417 coupled in series, in which the drain and gate of each transistor are tied together. As a result, the voltage drop across each transistor 412 and 417 is approximately equal to the gate-to-source voltage of the transistor.

The second stack of diode-connected transistors 420 comprises two diode-connected transistors 422 and 427 coupled in series, in which the drain and gate of each transistor are tied together. As a result, the voltage drop across each transistor 422 and 427 is approximately equal to the gate-to-source voltage of the transistor.

In one embodiment, the transistors in the second transistor stack 420 have a gate width that is m times as wide as the gate width of the transistors in the first transistor stack 410. In this aspect, each transistor in the first transistor stack 410 may have a K value given by:

$$\sqrt{K} = \frac{\sqrt{{mI}_{1}} - \sqrt{{I}_{2}}}{\sqrt{m} ( {V}_{gs 1} - {V}_{gs 2} )} \qquad ( 4 )$$

where I₁ is the current through the first transistor stack 410, I₂ is the current through the second transistor stack 420, V_{gs1} is the gate-to-source voltage of each transistor in the first transistor stack 410, and V_{gs2} is the gate-to-source voltage of each transistor in the second transistor stack 420. The currents I₁ and I₂ may be the same or different. In this embodiment, the measurement module 400 determines the gate-to-source voltage of each transistor in the first and second transistor stacks 410 and 420, and determines the K value based on equation (4), as discussed further below.

To measure the gate-to-source voltage V_{gs1} of each transistor in the first transistor stack 410, the controller closes the third mode switch 460 and opens all the other mode switches 160, 165 and 465. As a result, the first transistor stack 410 is connected to the negative input of the comparator 110. The current from the fourth current source 430 flows through the first transistor stack 410, resulting in a voltage drop across the first transistor stack 410. This voltage drop is connected to the negative input of the comparator 110 by the third mode switch 460.

The controller 125 also closes the first capacitor-select switch 360 to connect the first capacitor C1 to the positive input of the comparator 110. Initially, the controller 125 opens the first reset switch 150 and closes the second reset switch 155 to discharge the first capacitor C1 to zero volts. After the voltage across the first capacitor C1 is set to zero volts, the controller 125 closes the first reset switch 150 and opens the second reset switch 155. This connects the third current source 140 to the first capacitor C1 through the first reset switch 150, allowing the third current source 140 to charge the first capacitor C1. At about this time, the controller 125 triggers the counter 120 to begin counting.

The counter 120 stops counting when the voltage across the first capacitor C1 reaches the voltage across the first transistor stack 410. Thus, the count value when the counter 120 stops counting provides a measurement of the time it takes for the first capacitor C1 to charge to a voltage equal to the voltage across the first transistor stack 410. The calculation unit 122 may then determine the voltage across the first transistor stack 410 using equation (2), the time for the first capacitor C1 to charge up to the voltage across the first transistor stack 410 as indicated by the count value, and the time for the first capacitor C1 to charge up to the reference voltage Vref. In this example, the time for the first capacitor C1 to charge up to the voltage across the first transistor stack 410 corresponds to time T₂ in equation (2). The gate-to-source voltage V_{gs1} of each transistor in the first transistor stack 410 may then be determined by dividing the voltage across the first transistor stack 410 by two since the stack comprises two transistors.

To measure the gate-to-source voltage V_{gs2} of each transistor in the second transistor stack 420, the controller closes the fourth mode switch 465 and opens all the other mode switches 160, 165 and 460. As a result, the second transistor stack 420 is connected to the negative input of the comparator 110. The current from the fifth current source 435 flows through the second transistor stack 420, resulting in a voltage drop across the second transistor stack 420. This voltage drop is connected to the negative input of the comparator 110 by the fourth mode switch 465.

The controller 125 also closes the first capacitor-select switch 360 to connect the first capacitor C1 to the positive input of the comparator 110. Initially, the controller 125 opens the first reset switch 150 and closes the second reset switch 155 to discharge the first capacitor C1 to zero volts. After the voltage across the first capacitor C1 is set to zero volts, the controller 125 closes the first reset switch 150 and opens the second reset switch 155. This connects the third current source 140 to the first capacitor C1 through the first reset switch 150, allowing the third current source 140 to charge the first capacitor C1. At about this time, the controller 125 triggers the counter 120 to begin counting.

The counter 120 stops counting when the voltage across the first capacitor C1 reaches the voltage across the second transistor stack 420. Thus, the count value when the counter 120 stops counting provides a measurement of the time it takes for the first capacitor C1 to charge to a voltage equal to the voltage across the second transistor stack 420. The calculation unit 122 may then determine the voltage across the second transistor stack 410 using equation (2), the time for the first capacitor C1 to charge up the voltage across the second transistor stack 420 as indicated by the count value, and the time for the first capacitor C1 to charge up to the reference voltage Vref. In this example, the time for the first capacitor C1 to charge up to the voltage across the second transistor stack 420 corresponds to time T₂ in equation (2). The gate-to-source voltage V_{gs2} of each transistor in the second transistor stack 210 may then be determined by dividing the voltage across the second transistor stack 420 by two since the stack comprises two transistors.

After the gate-to-source voltage V_{gs1} of each transistor in the first transistor stack 410 and the gate-to-source voltage V_{gs2} of each transistor in the second transistor stack 420 are determined, the calculation unit 122 may determine the K value of each transistor in the first transistor stack 410 using equation (4) above.

The calculation unit 122 may also determine the threshold voltage Vₜₕ of the transistors from the measured gate-to-source voltages V_{gs1} and V_{gs2} using the following equation:

$${V}_{th} = \frac{( m \cdot {V}_{gs 1} - {V}_{gs 2} )}{( m + 1 )} . \qquad ( 5 )$$

Equation (5) assumes that the currents through the first transistor stack 410 and the second transistor stack 420 are the same.

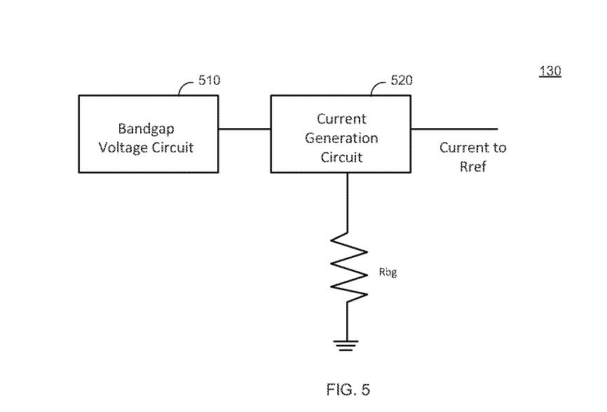

In one embodiment, the reference resistor Rref is an on-chip resistor. In this embodiment, the first current source 130 may comprise a bandgap voltage circuit 510, a current generation circuit 520, and an on-chip bandgap resistor Rbg, as shown in FIG. 5. The bandgap voltage circuit 510 generates a bandgap voltage Vbg (e.g., 1.2-1.3 V) that is approximately temperature and process independent. The bandgap voltage Vbg is input to the current generation circuit 520, which applies the bandgap voltage Vbg across the bandgap resistor Rbg to generate the current for the first current source 130. The current generation circuit 520 may do this, for example, by using a voltage regulator (not shown) to regulate the voltage across the bandgap resistor Rbg to be equal to the bandgap voltage Vbg, and a current mirror (not shown) to generate an output current for the reference resistor Ref that is equal to or proportional to the current though the bandgap resistor Rbg, which is equal to Vgb/Rbg.

The reference resistor Ref and the bandgap resistor Rbg are on the same chip and may be fabricated using the same unit size resistance to have almost identical PVT variations. Since Vref is proportional to the ratio Rref/Rbg, PVT variations are eliminated to a great extent. As a result, the reference voltage Vref is approximately independent of PVT and therefore can be known with high accuracy. The second third, fourth and fifth current sources may each be similarly implemented using an external resistor to generate the respective current.

Thus, embodiments of the present disclosure provide measurement modules capable of measuring different on-chip component parameters (e.g., resistance, capacitance, and MOS transistor parameters) using a single circuit topology. For example, the measurement module 400 is capable of switching between modes to measure the resistance of on-chip resistor R, the capacitances of on-chip capacitors C1 and C2, and parameters of transistors 412, 417, 422 and 427 using the same voltage comparator 110 and counter 120. This is in contrast to current measurement techniques that use two different circuit topologies (i.e., a high-resolution ADC and an oscillator) to measure on-chip resistance and on-chip capacitance.

Further, the measurement module 400 can be scaled to measure any number of on-chip component parameters. For example, the measurement module 400 can be scaled to measure the resistances of any number of on-chip resistors. This may be accomplished, for example, by connecting a separate mode switch between each of the on-chip resistors and the negative input of the voltage comparator 110. This allows the on-chip resistors to be selectively connected to the negative input of the comparator 110 by closing the respective mode switch. The resistance of a particular one of the resistors may then be measured by closing the respective mode switch to connect the resistor to the negative input of the voltage comparator 110, passing a current through the resistor from a current source, and performing the steps for measuring resistance discussed above. The measurement module 400 can also be scaled to measure the parameters of any number of transistors and/or measure the capacitances of any number of capacitors in a similar manner.

After the measurement module 400 determines an on-chip component parameter, the module 400 may store the parameter in a memory (e.g., an on-chip memory and/or an external memory) for later user and/or output the parameter to an external device (e.g., a workstation) for analysis. The measurement module 400 may also determine on-chip component parameters across a temperature range to determine temperature-dependent characteristics of the parameters. For example, the chip comprising the measurement module 400 may be placed in a chamber with a precisely controlled temperature. In this example, the chamber may be sequentially set to different temperatures. At each temperature setting, the measurement module 400 may determine the on-chip component parameters. For example, the measurement module 400 may determine the threshold voltage of the transistors 412, 417, 422 and 427 at each temperature setting to characterize the threshold voltage as a function of temperature. The measurement module 400 may also characterize the resistance of the on-chip resistor R and/or the capacitances of on-chip capacitors C1 and C2 as a function of temperature in a similar manner.

On-chip component parameters may be used to verify whether one or more circuits on a chip will function properly. For example, a circuit may be designed to function properly within a certain range of parameters (e.g., a range of threshold voltages). In this example, the measurement module 400 may be used to determine on-chip component parameters for the circuit, and a determination may be made whether the determined on-chip component parameters fall within this range. If the on-chip component parameters are outside this range, then the circuit may be considered non-functional.

In another example, a chip may include a PVT compensation circuit that adjusts one or more operating parameters (e.g., bias voltage, bias current, frequency, etc.) of the chip based on on-chip component parameters of the chip to achieve a desired level of performance. In this example, the on-chip component parameters used by the PVT compensation circuit may be provided by the measurement module 400.

In yet another example, on-chip component parameters for different chips may be used to determine process corners for a fabrication process. In this example, each chip may have a measurement module 400 that determines on-chip components for the chip. Also, the chips may be obtained from two or more different corner lots, in which process parameters for each corner lot are intentionally offset from normal process parameters to simulate extremes in process parameters. In this example, the determined on-chip component parameters for the different chips may be used to determine the distribution of on-chip component parameters across the chips. For the example of threshold voltage, the distribution of threshold voltages across the chips may be analyzed to determine low and high extremes in the threshold voltages. The low and high extremes may then be used to define process corners for the fabrication process. For example, the low extreme may be used to define a fast process corner since lower threshold voltages translate into faster speeds. The high extreme may be used to define a slow process corner since higher threshold voltages translate into slower speeds.

After the fast and slow process corners are determined, transistors on a chip may be categorized into one of three categories (slow, typical and fast) based on the threshold voltage determined by the respective measurement module 400. For example, if the determined threshold voltage falls near the low end of the threshold voltage distribution, then the transistors of the chip may be categorized as fast. If the determined threshold voltage falls near the high end of the threshold voltage distribution, then the transistors of the chip may be categorized as slow. If the determined threshold voltage falls near the middle of the threshold voltage distribution, then the transistors of the chip may be categorized as typical.

In one embodiment, one or more operating parameters of a chip may be adjusted depending on whether transistors of the chip are categorized as slow, typical or fast. For example, if the transistors of the chip are categorized as fast, then an operating frequency of the chip may be increased.

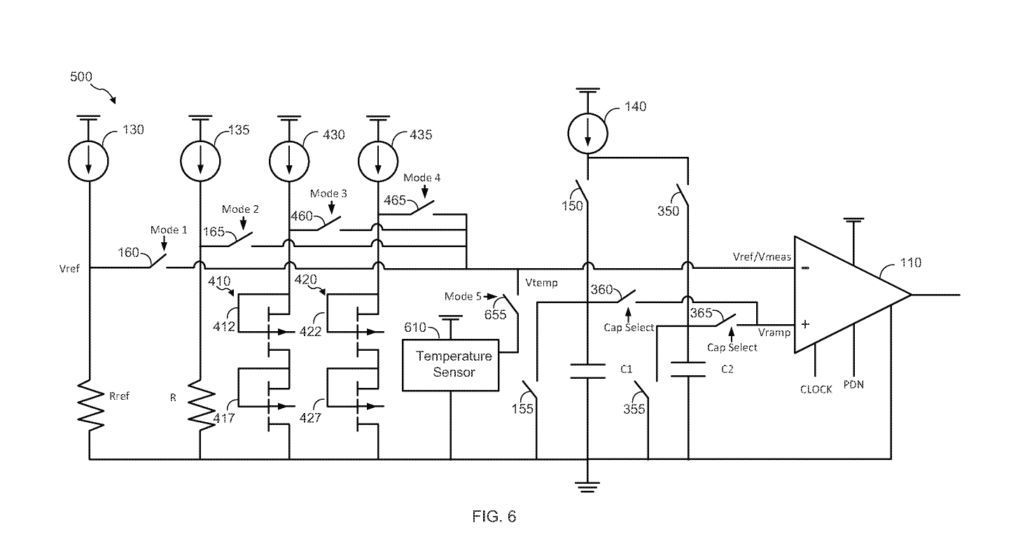

FIG. 6 shows a measurement module 600 for calibrating an on-chip temperature sensor 610 according to an embodiment of the present disclosure. The module 600 is similar to the module 400 in FIG. 4 and further comprises a fifth mode switch 655 connected between the temperature sensor 610 and the negative input of the voltage comparator 110.

The on-chip temperature sensor 610 may be used to determine a temperature of the chip by outputting a voltage that is function of the temperature. To calibrate the temperature sensor 610, the chip may be placed in a chamber with a precisely controlled temperature. The chamber may then be sequentially set to different temperatures. At each temperature setting, the measurement module 600 may determine the output voltage of the temperature sensor 610. The output voltages at the different temperature settings may be used to generate a temperature table that maps the output voltages to the corresponding temperatures. After the temperature table is generated, the temperature of the chip may be determined by using the measurement module 600 to determine the output voltage of the temperature sensor 610, and consulting the temperature table to determine the temperature based on the determined output voltage.

To measure the output voltage of the temperature sensor 610, the controller 125 closes the fifth mode switch 655 and opens all the other mode switches. As a result, the output voltage of the temperature sensor 610 is connected to the negative input of the comparator 110.

The controller 125 also closes the first capacitor-select switch 360 to connect the first capacitor C1 to the positive input of the comparator 110. Initially, the controller 125 opens the first reset switch 150 and closes the second reset switch 155 to discharge the first capacitor C1 to zero volts. After the voltage across the first capacitor C1 is set to zero volts, the controller 125 closes the first reset switch 150 and opens the second reset switch 155. This connects the third current source 140 to the first capacitor C1 through the first reset switch 150, allowing the third current source 140 to charge the first capacitor C1. At about this time, the controller 125 triggers the counter 120 to begin counting.

The counter 120 stops counting when the voltage across the first capacitor C1 reaches the output voltage of the temperature sensor 610. Thus, the count value when the counter 120 stops counting provides a measurement of the time it takes for the first capacitor C1 to charge to a voltage equal to the output voltage of the temperature sensor 610. The calculation unit 122 may then determine the output voltage of the temperature sensor 610 using equation (2), the time for the first capacitor C1 to charge up to the output voltage of the temperature sensor 610 as indicated by the count value, and the time for the first capacitor C1 to charge up to the reference voltage Vref. In this example, the time for the first capacitor C1 to charge up to the output voltage of the temperature sensor 610 corresponds to time T₂ in equation (2).

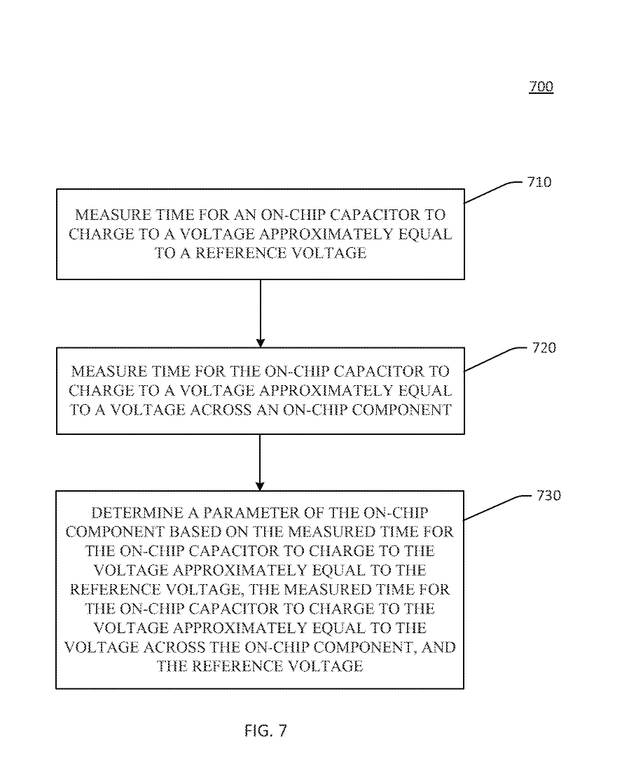

FIG. 7 is a flow diagram of a method 700 for measuring one or more on-chip component parameters. The method 700 may be performed by any of the measure modules 100, 300, 400 and 500 discussed above.

In step 710, a time for an on-chip capacitor to charge to a voltage approximately equal to a reference voltage is measured. This may be done, for example, by charging the on-chip capacitor (on-chip capacitor C or C1) with a current source (e.g., the third current source 140) after the on-chip capacitor has been discharged, starting a counter (e.g., the counter 120) when the on-chip capacitor starts charging, and stopping the counter when the voltage across the on-chip capacitor reaches the reference voltage (e.g., Vref). In this example, the count value at which the counter stops counting provides a measure of the time for the on-chip to charge to the voltage approximately equal to the reference voltage.

In step 720, a time for the on-chip capacitor to charge to a voltage approximately equal to a voltage across an on-chip component is measured. This may be done, for example, by charging the on-chip capacitor (on-chip capacitor C or C1) with a current source (e.g., the third current source 140) after the on-chip capacitor has been discharged, starting a counter (e.g., the counter 120) when the on-chip capacitor starts charging, and stopping the counter when the voltage across the on-chip capacitor reaches the voltage across the on-chip component. In this example, the count value at which the counter stops counting provides a measure of the time for the on-chip to charge to the voltage approximately equal to the voltage across the on-chip component.

In step 730, a parameter of the on-chip component is determined based on the measured time for the on-chip capacitor to charge to the voltage approximately equal to the reference voltage, the measured time for the on-chip capacitor to charge to the voltage approximately equal to the voltage across the on-chip component, and the reference voltage. For example, the parameter of the on-chip component may be determined based on equation (2) above.

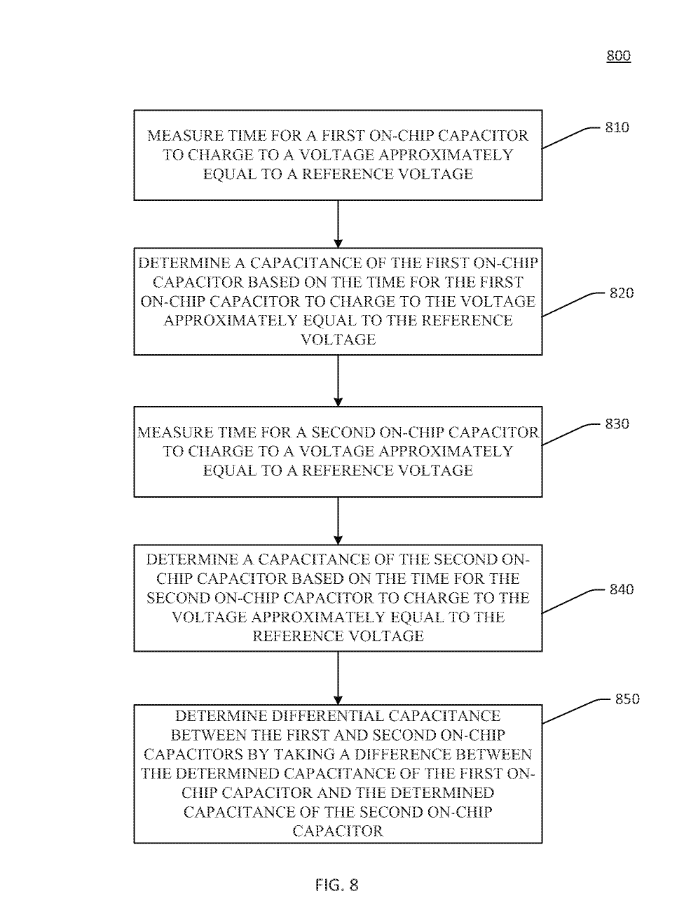

FIG. 8 is a flow diagram of a method 800 for measuring differential capacitance. The method 800 may be performed by any of the measure modules 300, 400 and 500 discussed above.

In step 810, a time for a first on-chip capacitor to charge to a voltage approximately equal to a reference voltage is measured. In step 820, a capacitance of the first on-chip capacitor is determined based on the measured time for the first on-chip capacitor to charge to the voltage approximately equal to the reference voltage, and the reference voltage.

In step 830, a time for a second on-chip capacitor to charge to a voltage approximately equal to the reference voltage is measured. In step 840, a capacitance of the second on-chip capacitor is determined based on the measured time for the second on-chip capacitor to charge to the voltage approximately equal to the reference voltage, and the voltage reference.

In step 850, a differential capacitance between the first and second on-chip capacitors is determined by taking a difference between the determined capacitance of the first on-chip capacitor and the determined capacitance of the second on-chip capacitor. The differential capacitance can be used to re-determine the capacitances of the first and second capacitors with higher accuracy since the differential capacitance removes sources of measurement errors that are common to both capacitors, as discussed above.

Those skilled in the art will further appreciate that the various illustrative blocks, circuits, and steps described in connection with the disclosure herein may be implemented as electronic hardware, computer software, or combinations of both. To clearly illustrate this interchangeability of hardware and software, various illustrative components, blocks, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative blocks and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the disclosure herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection may be properly termed a computer-readable medium to the extent involving non-transient storage of transmitted signals. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium, to the extent the signal is retained in the transmission chain on a storage medium or device memory for any non-transient length of time. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A method for measuring one or more on-chip component parameters, comprising:
measuring a time for an on-chip capacitor to charge to a voltage approximately equal to a reference voltage;
measuring a time for the on-chip capacitor to charge to a voltage approximately equal to a voltage across an on-chip component; and
determining a parameter of the on-chip component based on the measured time for the on-chip capacitor to charge to the voltage approximately equal to the reference voltage, the measured time for the on-chip capacitor to charge to the voltage approximately equal to the voltage across the on-chip component, and the reference voltage.

2. The method of claim 1, wherein measuring the time for the on-chip capacitor to charge to the voltage approximately equal to the reference voltage comprises:
discharging the on-chip capacitor; and
after the on-chip capacitor is discharged, charging the on-chip capacitor with a current source.

3. The method of claim 1, further comprising:
generating a current by applying a regulated voltage across a first on-chip resistor; and
passing the current through a second on-chip resistor to generate the reference voltage.

4. The method of claim 3, wherein the regulated voltage is approximately equal to a bandgap voltage.

5. The method of claim 1, wherein the on-chip component comprises an on-chip resistor, and the parameter of the on-chip component comprises resistance.

6. The method of claim 1, wherein the on-chip component comprises one or more transistors, and the parameter of the on-chip component comprises at least one of a K value and a threshold voltage.

7. The method of claim 6, wherein the one or more transistors comprise at least two diode-connected transistors.

8. An apparatus for measuring one or more on-chip component parameters, comprising:
means for measuring a time for an on-chip capacitor to charge to a voltage approximately equal to a reference voltage;
means for measuring a time for the on-chip capacitor to charge to a voltage approximately equal to a voltage across an on-chip component; and
means for determining a parameter of the on-chip component based on the measured time for the on-chip capacitor to charge to the voltage approximately equal to the reference voltage, the measured time for the on-chip capacitor to charge to the voltage approximately equal to the voltage across the on-chip component, and the reference voltage.

9. The apparatus of claim 8, wherein the means for measuring the time for the on-chip capacitor to charge to the voltage approximately equal to the reference voltage comprises:
means for discharging the on-chip capacitor; and
means for charging the on-chip capacitor with a current source.

10. The apparatus of claim 8, further comprising:
means for generating a current by applying a regulated voltage across a first on-chip resistor; and
means for passing the current through a second on-chip resistor to generate the reference voltage.

11. The apparatus of claim 10, wherein the regulated voltage is approximately equal to a bandgap voltage.

12. The apparatus of claim 8, wherein the on-chip component comprises an on-chip resistor, and the parameter of the on-chip component comprises resistance.

13. The apparatus of claim 8, wherein the on-chip component comprises one or more transistors, and the parameter of the on-chip component comprises at least one of a K value and a threshold voltage.

14. The apparatus of claim 13, wherein the one or more transistors comprise at least two diode-connected transistors.

15. An apparatus for measuring one or more on-chip component parameters, comprising:
a voltage comparator having a first input, a second input, and an output;
a first mode switch for selectively connecting a reference voltage to the first input of the voltage comparator;
a second mode switch for selectively connecting an on-chip component to the first input of the voltage comparator;
an on-chip capacitor coupled to the second input of the comparator;
a counter coupled to the output of the voltage comparator; and
a controller, wherein, in a first measurement mode, the controller is configured to close the first mode switch, open the second mode switch and trigger the counter to start counting, and, in a second measurement mode, the controller is configured to open the first mode switch, close the second mode switch and trigger the counter to start counting;
wherein the counter is configured to stop counting when the output of the voltage comparator toggles from a first output value to a second output value.

16. The apparatus of claim 15, wherein the first input is a negative input of the voltage comparator, the second input is a positive input of the voltage comparator, the first output value is a logic zero value, and the second output value is a logic one value.

17. The apparatus of claim 15, further comprising:
a first reset switch for selectively connecting a terminal of the on-chip capacitor to a ground, wherein the terminal of the on-chip capacitor is coupled to the second input of the voltage comparator;
a second reset switch for selectively connecting the terminal of the on-chip capacitor to a current source;
wherein, in each of the first and second measurement modes, the controller is configured to open the second reset switch and close the first reset switch to discharge the on-chip capacitor, and, after the on-chip capacitor is discharged, to open the first reset switch and close the second reset switch to charge the on-chip capacitor using the current source.

18. The apparatus of claim 17, wherein, in each of the first and second measurement modes, the controller is configured to trigger the counter to start counter when the on-chip capacitor starts charging.

19. The apparatus of claim 15, further comprising a calculation unit, wherein, in the first measurement mode, the calculation unit is configured to determine a time for the on-chip capacitor to charge to a voltage approximately equal to the reference voltage based on a count value at which the counter stops counting in the first measurement mode, and, in the second measurement mode, the calculation unit is configured to determine a time for the on-chip capacitor to charge to a voltage approximately equal to a voltage across the on-chip component based on a count value at which the counter stops counting in the second measurement mode.

20. The apparatus of claim 19, wherein the calculation unit is configured to determine a parameter of the on-chip component based on the time for the on-chip capacitor to charge to the voltage approximately equal to the reference voltage, the time for the on-chip capacitor to charge to the voltage approximately equal to the voltage across the on-chip component, and the reference voltage.

21. The apparatus of claim 20, wherein the on-chip component comprises an on-chip resistor, and the parameter of the on-chip component comprises resistance.

22. The apparatus of claim 20, wherein the on-chip component comprises one or more transistors, and the parameter of the on-chip component comprises at least one of a K value and a threshold voltage.

23. A method for measuring differential capacitance, comprising:
measuring a time for a first on-chip capacitor to charge to a voltage approximately equal to a reference voltage;
determining a capacitance of the first on-chip capacitor based on the measured time for the first on-chip capacitor to charge to the voltage approximately equal to the reference voltage, and the reference voltage;
measuring a time for a second on-chip capacitor to charge to a voltage approximately equal to the reference voltage;
determining a capacitance of the second on-chip capacitor based on the measured time for the second on-chip capacitor to charge to the voltage approximately equal to the reference voltage, and the voltage reference; and
determining a differential capacitance between the first and second on-chip capacitors by taking a difference between the determined capacitance of the first on-chip capacitor and the determined capacitance of the second on-chip capacitor.

24. The method of claim 23, further comprising:
generating a current by applying a regulated voltage across a first on-chip resistor; and
passing the current through a second on-chip resistor to generate the reference voltage.

25. The method of claim 24, wherein the regulated voltage is approximately equal to a bandgap voltage.

26. The method of claim 23, wherein the first and second on-chip capacitors are charged with the same current source at different times.

27. The method of claim 23, further comprising re-determining the capacitance of the first on-chip capacitor based on the determined differential capacitance and the capacitance of the first on-chip capacitor relative to the capacitance of the second on-chip capacitor.

28. The method of claim 27, wherein the capacitance of the first on-chip capacitor relative to the capacitance of the second on-chip capacitor is determined based on an area of the first on-chip capacitor relative to an area of the second on-chip capacitor.
